(19) United States
(12) Patent Application Publication
(10) Pub. No.: US 2025/0038479 A1
(43) Pub. Date: Jan. 30, 2025

(54) SEMICONDUCTOR STRUCTURE AND SEMICONDUCTOR STRUCTURE PREPARATION METHOD

(71) Applicant: Enkris Semiconductor (Wuxi), Ltd., Wuxi city (CN)

(72) Inventor: Kai CHENG, Jiangsu (CN)

(21) Appl. No.: 18/610,763

(22) Filed: Mar. 20, 2024

(30) Foreign Application Priority Data
Jul. 26, 2023 (CN) 202310928720.3

(51) Int. Cl. H01S 5/12

(52) U.S. Cl. CPC H01S 5/1237

(57) ABSTRACT

Provided are a semiconductor structure and a semiconductor structure preparation method. The semiconductor structure includes a substrate, a first reflector structure, a second reflector structure, and a light-emitting structure. The substrate includes a first region, a second region, and a third region disposed between the first region and the second region. The first reflector structure is disposed in the first region of the substrate. The second reflector structure is disposed in the second region of the substrate and disposed on the same side of the substrate as the first reflector structure. The light-emitting structure is disposed in the third region of the substrate and disposed on the same side of the substrate as the first reflector structure. Each of the reflective surface of the first reflector structure and the reflective surface of the second reflector structure faces the sidewall of the light-emitting structure.

### CROSS-REFERENCE TO RELATED APPLICATIONS

This application claims priority to Chinese patent application No. 202310928720.3 filed with the China National Intellectual Property Administration (CNIPA) on Jul. 26, 2023, the disclosure of which is incorporated herein by reference in its entirety.

### TECHNICAL FIELD

Embodiments of the present disclosure relate to the field of semiconductor technology and, in particular, to a semiconductor structure and a semiconductor structure preparation method.

### BACKGROUND

A semiconductor laser, also referred to as a laser diode, uses a semiconductor material such as gallium arsenide (GaAs), indium phosphide (InP), gallium nitride (GaN), aluminum nitride (AlN), cadmium sulfide (CdS), or zinc sulfide (ZnS) as a working substance. The semiconductor laser has the advantages of a small volume, high efficiency, and a long service life.

Currently, a first reflector, an active region, and a second reflector in the semiconductor laser are stacked on a substrate. The reflector is generally made of a dielectric material, such as a stacked SiO₂/SiN material. When a Group III nitride material is prepared on the dielectric material, the crystal quality of the film is relatively low. Therefore, the active region is stacked on the reflector, and the problem of the low crystal quality of the active region exists, which causes the light emission efficiency of the semiconductor laser to be reduced, increases the risk of film cracking in the semiconductor laser, and affects the service life of the semiconductor laser.

### SUMMARY

Embodiments of the present disclosure provide a semiconductor structure and a semiconductor structure preparation method to improve the light emission efficiency and service life of the semiconductor structure.

According to the present disclosure, a semiconductor structure is provided. The semiconductor structure includes a substrate, a first reflector structure, a second reflector structure, and a light-emitting structure.

The substrate includes a first region, a second region, and a third region disposed between the first region and the second region.

The first reflector structure is disposed in the first region of the substrate.

The second reflector structure is disposed in the second region of the substrate and disposed on the same side of the substrate as the first reflector structure.

The light-emitting structure is disposed in the third region of the substrate and disposed on the same side of the substrate as the first reflector structure.

The reflective surface of the first reflector structure and the reflective surface of the second reflector structure face the sidewall of the light-emitting structure.

In an embodiment, the first reflector structure and/or the second reflector structure is a Bragg reflector structure.

The first reflector structure includes a first sub-dielectric layer covering the sidewall of the light-emitting structure, and the first sub-dielectric layer is provided with multiple first grooves uniformly distributed and a third semiconductor layer prepared in each first groove.

The second reflector structure includes a second sub-dielectric layer covering the sidewall of the light-emitting structure, and the second sub-dielectric layer is provided with multiple second grooves uniformly distributed and a fourth semiconductor layer prepared in each second groove.

In an embodiment, the first groove extends along a first direction, and the multiple first grooves are arranged at intervals along a second direction.

The second groove extends along the first direction, and the multiple second grooves are arranged at intervals along the second direction.

The second direction is a direction in which the first reflector structure is pointing to the light-emitting structure, and the first direction and the second direction are perpendicular to each other.

In an embodiment, the number of the first grooves is less than the number of the second grooves.

In an embodiment, the first groove has a width less than 100 nm, and the interval between the multiple first grooves is less than 150 nm.

The second groove has a width less than 100 nm, and the interval between the multiple second grooves is less than 150 nm.

In an embodiment, each of the first sub-dielectric layer and the second sub-dielectric layer is a single layer of material, the material of the first sub-dielectric layer includes SiO₂ or SiN, and the material of the second sub-dielectric layer includes SiO₂ or SiN.

Alternatively, each of the first sub-dielectric layer and the second sub-dielectric layer is a stacked material layer, each of the first sub-dielectric layer and the second sub-dielectric layer includes multiple stacked distributed Bragg reflector (DBR) material layers perpendicular to the substrate, the material of the first sub-dielectric layer include SiO₂ and SiN, and the material of the second sub-dielectric layer include SiO₂ and SiN.

In an embodiment, a first groove extends through or partially extends through the first sub-dielectric layer; and/or a second groove extends through or partially extends through the second sub-dielectric layer.

In an embodiment, the material of the third semiconductor layer and the material of the fourth semiconductor layer each include a Group III nitride material.

The first reflector structure further includes a first partition groove extending along the second direction and intersecting the multiple first grooves, and the Group III nitride material is prepared in the first partition groove.

The second reflector structure further includes a second partition groove extending along the second direction and intersecting the multiple second grooves, and the Group III nitride material is prepared in the second partition groove.

In an embodiment, the Group III nitride material includes a gallium nitride material.

The first direction is a [11-20] crystal orientation of a hexagonal crystal system of the gallium nitride material; and the second direction is a [1-100] crystal orientation of the hexagonal crystal system of the gallium nitride material.

In an embodiment, the depth of the first partition groove is greater than or equal to the thickness of the first reflector structure along a direction perpendicular to the substrate; and/or the depth of the second partition groove is greater than or equal to the thickness of the second reflector structure along the direction perpendicular to the substrate.

In an embodiment, the light-emitting structure includes a first semiconductor layer, an active layer, and a second semiconductor layer which are sequentially stacked on the substrate.

In an embodiment, each of the material of the first semiconductor layer, the material of the active layer, and the material of the second semiconductor layer includes a Group III nitride material.

In an embodiment, the conductivity type of the first semiconductor layer and the conductivity type of the second semiconductor layer are opposite to each other.

In an embodiment, the semiconductor structure further includes a first electrode and a second electrode, where the first electrode is electrically connected to the first semiconductor layer, and the second electrode is electrically connected to the second semiconductor layer.

According to the present disclosure, a semiconductor structure preparation method is provided. The semiconductor structure preparation method is used for preparing the semiconductor structure according to any embodiment of the present disclosure. The semiconductor structure preparation method includes the steps described below.

A substrate is provided, and the substrate includes a first region, a second region, and a third region disposed between the first region and the second region.

A first reflector structure is formed in the first region of the substrate and a second reflector structure is formed in the second region of the substrate.

A light-emitting structure is formed in the third region of the substrate, the first reflector structure, the second reflector structure, and the light-emitting structure are disposed on the same side of the substrate, and each of the reflective surface of the first reflector structure and the reflective surface of the second reflector structure faces the sidewall of the light-emitting structure.

In an embodiment, after the first reflector structure is formed in the first region of the substrate and the second reflector structure is formed in the second region of the substrate, the light-emitting structure is formed in the third region of the substrate.

Alternatively, after the light-emitting structure is formed in the third region of the substrate, the first reflector structure is formed in the first region of the substrate and the second reflector structure is formed in the second region of the substrate.

In an embodiment, the step of forming the first reflector structure in the first region of the substrate and the second reflector structure in the second region of the substrate includes the steps described below

A dielectric material layer is formed on a side surface of the substrate, where the dielectric material layer has a single-film structure or a multi-film structure.

The dielectric material layer is patterned so that multiple first grooves extending along a first direction and arranged at uniform intervals along a second direction are formed in the first region and multiple second grooves extending along the first direction and arranged at uniform intervals along the second direction are formed in the second region, where the second direction is a direction in which the first reflector structure is pointing to the light-emitting structure, and the first direction and the second direction are perpendicular to each other.

A Group III nitride material is prepared in each first groove to form a third semiconductor layer, and a Group III nitride material is prepared in each second groove to form a fourth semiconductor layer, where a dielectric material layer in the first region is used for forming a first sub-dielectric layer and a dielectric material layer in the second region is used for forming a second sub-dielectric layer.

In an embodiment, the step of preparing the Group III nitride material in each first groove to form the third semiconductor layer, and preparing the Group III nitride material in each second groove to form the fourth semiconductor layer includes the steps described below.

The dielectric material layer is patterned so that a first partition groove extending along the second direction and intersecting the multiple first grooves is formed in the first region and a second partition groove extending along the second direction and intersecting the multiple second grooves is formed in the second region, where the depth of the first partition groove is greater than or equal to the depth of the first groove, and the depth of the second partition groove is greater than or equal to the depth of the second groove.

The Group III nitride material is prepared in the first partition groove and the second partition groove.

The Group III nitride material is prepared from the first partition groove to the first groove in an epitaxial lateral overgrowth (ELOG) manner so that the third semiconductor layer is formed, and the Group III nitride material is prepared from the second partition groove to the second groove in the ELOG manner so that the fourth semiconductor layer is formed.

In an embodiment, the step of forming the light-emitting structure in the third region of the substrate includes the steps below.

A dielectric material layer in the third region is etched until the substrate is exposed.

A first semiconductor layer is formed in the third region.

An active layer is formed on the side surface of the first semiconductor layer facing away from the substrate.

A second semiconductor layer is formed on the side surface of the active layer facing away from the substrate.

In an embodiment, after the light-emitting structure is formed in the third region of the substrate, the method further includes the steps below.

A first electrode is formed on the side of the second semiconductor layer facing away from the substrate.

A second electrode is formed on the side of the substrate facing away from the light-emitting structure.

Alternatively, after the light-emitting structure is formed in the third region of the substrate, the method further includes the steps below.

A part of the second semiconductor layer and a part of the active layer are etched sequentially until a part of the first semiconductor layer is exposed.

A first electrode is formed on the side of the second semiconductor layer facing away from the substrate.

A second electrode is formed on the side of the exposed part of the first semiconductor layer facing away from the substrate. It is to be understood that the content described in this section is neither intended to identify key or critical features of the embodiments of the present disclosure nor intended to limit the scope of the present disclosure. Other features of the present disclosure become easily understood through the description hereinafter.

### BRIEF DESCRIPTION OF DRAWINGS

To illustrate technical schemes in embodiments of the present disclosure more clearly, drawings used in the description of the embodiments are briefly described below. Apparently, the drawings described below only illustrate part of the embodiments of the present disclosure, and those of ordinary skill in the art may obtain other drawings based on the drawings on the premise that no creative work is done.

FIG. 1 is a perspective view of a semiconductor laser according to an embodiment of the present disclosure;

FIG. 2 is a sectional view of a structure shown in FIG. 1 taken along a section line AA1;

FIG. 3 is a perspective view of another semiconductor laser according to an embodiment of the present disclosure;

FIG. 4 is another sectional view according to an embodiment of the present disclosure;

FIG. 5 is another sectional view according to an embodiment of the present disclosure;

FIG. 6 is a flowchart of a semiconductor laser preparation method according to an embodiment of the present disclosure;

FIG. 7 is a flowchart of another semiconductor laser preparation method according to an embodiment of the present disclosure;

FIG. 8 is a sectional view for step S210 in a semiconductor laser preparation method according to an embodiment of the present disclosure;

FIG. 9 is a sectional view for step S220 in a semiconductor laser preparation method according to an embodiment of the present disclosure;

FIG. 10 is a sectional view for step S230 in a semiconductor laser preparation method according to an embodiment of the present disclosure;

FIG. 11 is a sectional view for step S240 in a semiconductor laser preparation method according to an embodiment of the present disclosure;

FIG. 12 is a sectional view for step S250 in a semiconductor laser preparation method according to an embodiment of the present disclosure;

FIG. 13 is a sectional view for step S250 in a semiconductor laser preparation method according to an embodiment of the present disclosure;

FIG. 14 is a sectional view for step S250 in a semiconductor laser preparation method according to an embodiment of the present disclosure;

FIG. 15 is a sectional view for step S250 in a semiconductor laser preparation method according to an embodiment of the present disclosure;

FIG. 16 is a sectional view for step S250 in a semiconductor laser preparation method according to an embodiment of the present disclosure;

FIG. 17 is a flowchart of another semiconductor laser preparation method according to an embodiment of the present disclosure;

FIG. 18 is a sectional view for step S340 in a semiconductor laser preparation method according to an embodiment of the present disclosure;

FIG. 19 is a sectional view for step S360 in a semiconductor laser preparation method according to an embodiment of the present disclosure;

FIG. 20 is a sectional view for step S370 in a semiconductor laser preparation method according to an embodiment of the present disclosure;

FIG. 21 is a sectional view for step S370 in a semiconductor laser preparation method according to an embodiment of the present disclosure;

FIG. 22 is a sectional view for step S380 in a semiconductor laser preparation method according to an embodiment of the present disclosure;

FIG. 23 is a sectional view for step S390 in a semiconductor laser preparation method according to an embodiment of the present disclosure;

FIG. 24 is a sectional view for step S3100 in a semiconductor laser preparation method according to an embodiment of the present disclosure;

FIG. 25 is a flowchart of another semiconductor laser preparation method according to an embodiment of the present disclosure;

FIG. 26 is a sectional view for step S430 in a semiconductor laser preparation method according to an embodiment of the present disclosure;

FIG. 27 is a sectional view for step S430 in a semiconductor laser preparation method according to an embodiment of the present disclosure;

FIG. 28 is a sectional view for step S440 in a semiconductor laser preparation method according to an embodiment of the present disclosure;

FIG. 29 is a sectional view for step S440 in a semiconductor laser preparation method according to an embodiment of the present disclosure;

FIG. 30 is a sectional view for step S450 in a semiconductor laser preparation method according to an embodiment of the present disclosure;

FIG. 31 is a flowchart of another semiconductor laser preparation method according to an embodiment of the present disclosure;

FIG. 32 is a sectional view for step S550 in a semiconductor laser preparation method according to an embodiment of the present disclosure; and

FIG. 33 is a sectional view for step S570 in a semiconductor laser preparation method according to an embodiment of the present disclosure.

### DETAILED DESCRIPTION

To make the technical schemes of the present disclosure better understood by those skilled in the art, the technical schemes in embodiments of the present disclosure are described below clearly and completely in conjunction with drawings in the embodiments of the present disclosure. Apparently, the embodiments described below are part, not all, of the embodiments of the present disclosure. Based on the embodiments of the present disclosure, all other embodiments obtained by those of ordinary skill in the art on the premise that no creative work is done are within the scope of the present disclosure.

It is to be noted that terms such as “first” and “second” in the description, claims, and drawings of the present disclosure are used for distinguishing between similar objects and are not necessarily used for describing a particular order or sequence. It is to be understood that the data used in this manner is interchangeable in appropriate cases so that the embodiments of the present disclosure described herein can be implemented in an order not illustrated or described herein. In addition, the terms “including”, “having”, and any other variations thereof are intended to cover a non-exclusive inclusion. For example, a process, a method, a system, a product, or a device that includes a series of steps or units may include not only the expressly listed steps or units but also other steps or units that are not expressly listed or are inherent to the process, the method, the product, or the device.

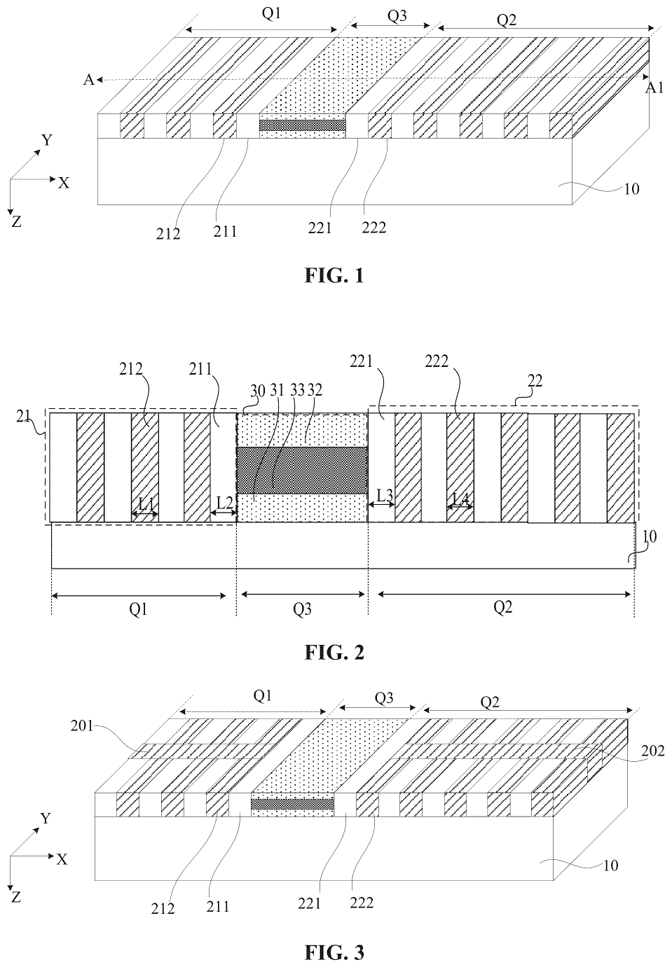

The embodiments of the present disclosure provide a semiconductor structure. FIG. 1 is a perspective view of a semiconductor laser according to an embodiment of the present disclosure, and FIG. 2 is a sectional view of a structure shown in FIG. 1 taken along a section line AA1. Referring to FIGS. 1 and 2, the semiconductor structure includes a substrate 10, a first reflector structure 21, a second reflector structure 22, and a light-emitting structure 30.

The substrate 10 includes a first region Q1, a second region Q2, and a third region Q3 disposed between the first region Q1 and the second region Q2.

The first reflector structure 21 is disposed in the first region Q1 of the substrate 10.

The second reflector structure 22 is disposed in the second region Q2 of the substrate 10 and on the same side of the substrate 10 as the first reflector structure 21.

The light-emitting structure 30 is disposed in the third region Q3 of the substrate 10 and on the same side of the substrate 10 as the first reflector structure 21. The reflective surface of the first reflector structure 21 and the reflective surface of the second reflector structure 22 face the sidewall of the light-emitting structure 30.

The third region Q3 is disposed between the first region Q1 and the second region Q2 and connects to the first region Q1 and the second region Q2. The first reflector structure 21, the second reflector structure 22, and the light-emitting structure 30 are disposed on the same side of the substrate 10 and are disposed in the first region Q1 of the substrate 10, the second region Q2 of the substrate 10, and the third region Q3 of the substrate 10, respectively. The first reflector structure 21, the light-emitting structure 30, and the second reflector structure 22 are disposed side by side on the same side of the substrate 10, the light-emitting structure 30 is disposed between the first reflector structure 21 and the second reflector structure 22, and the reflective surface of the first reflector structure 21 and the reflective surface of the second reflector structure 22 face the sidewall of the light-emitting structure 30 so that the first reflector structure 21 and the second reflector structure 22 reflect light generated by the light-emitting structure 30 in a direction parallel to the substrate 10. In this manner, resonance is generated between the first reflector structure 21 and the second reflector structure 22, and the light is emitted along the direction parallel to the substrate 10.

The light-emitting structure 30 is directly formed on the substrate 10, instead of being stacked on a reflector structure in the related art. Therefore, the Group III nitride material of the light-emitting structure 30 is prevented from being formed on a dielectric material film so that the crystal quality of the light-emitting structure 30 is effectively improved and light emission efficiency is improved. The material of the substrate 10 may be silicon, sapphire, SiC, AlN, GaN, or the like. In an embodiment, a buffer layer may also be disposed on the surface of the substrate 10 facing a semiconductor layer so that the quality of the substrate 10 and the surface of the substrate 10 can meet the requirements for directly preparing the light-emitting structure 30. The crystal quality of the Group III nitride material of the light-emitting structure 30 is improved, thereby improving the light emission efficiency of the semiconductor structure, reducing the risk of film cracking in the semiconductor structure, and ensuring the service life of the semiconductor structure. The buffer layer may have the same material as the light-emitting structure 30 or a material similar in property to the light-emitting structure 30. Thus, the crystal quality of the Group III nitride material of the light-emitting structure 30 can be further improved, the light emission efficiency of the semiconductor structure can be further improved, and the service life of the semiconductor structure can be further ensured.

Regarding the semiconductor structure provided by the embodiments of the present disclosure, the first reflector structure, the light-emitting structure, and the second reflector structure are disposed side by side on the same side of the substrate, and it is only necessary to ensure that the quality and the surface of the substrate can meet the requirements for directly preparing the light-emitting structure so that the light emission efficiency of the semiconductor structure can be improved, the risk of film cracking in the semiconductor structure can be reduced, and the service life of the semiconductor structure can be ensured.

In an embodiment of the present disclosure, referring to FIGS. 1 and 2, the first reflector structure 21 and/or the second reflector structure 22 is a Bragg reflector structure.

The first reflector structure 21 includes a first sub-dielectric layer 211 covering the sidewall of the light-emitting structure 30, and the first sub-dielectric layer 211 is provided with multiple first grooves uniformly distributed and a third semiconductor layer 212 prepared in the multiple first grooves.

The second reflector structure 22 includes a second sub-dielectric layer 221 covering the sidewall of the light emitting structure 30, and the second sub-dielectric layer 221 is provided with multiple second grooves uniformly distributed and a fourth semiconductor layer 222 prepared in the multiple second grooves.

The first reflector structure 21 includes the first sub-dielectric layer 211 covering the sidewall of the light-emitting structure 30, and the first sub-dielectric layer 211 is provided with the multiple first grooves uniformly distributed and the third semiconductor layer 212 prepared in each first groove. Along a direction from the first reflector structure 21 to the light-emitting structure 30, the third semiconductor layer 212 and the first sub-dielectric layer 211 are alternately disposed in sequence and the refractive index of the material of the third semiconductor layer 212 is different from the refractive index of the material of the first sub-dielectric layer 211. Thus, a Bragg reflector structure in which multiple material layers are disposed in a manner of alternatively high and low refractive indexes is formed.

The second reflector structure 22 includes the second sub-dielectric layer 221 covering the sidewall of the light emitting structure 30, and the second sub-dielectric layer 221 is provided with the multiple second grooves uniformly distributed and the fourth semiconductor layer 222 prepared in each second groove. Along a direction from the second reflector structure 22 to the light-emitting structure 30, the fourth semiconductor layer 222 and the second sub-dielectric layer 221 are alternately disposed in sequence and the refractive index of the material of the fourth semiconductor layer 222 is different from the refractive index of the material of the second sub-dielectric layer 221. Thus, a Bragg reflector structure in which multiple material layers are disposed in a manner of alternatively high and low refractive indexes is formed.

In an embodiment of the present disclosure, the first groove extends along the first direction Y, and the multiple first grooves are arranged at intervals along the second direction X; and the second groove extends along the first direction Y, and the multiple second grooves are arranged at intervals along the second direction X; where the second direction X is the direction in which the first reflector structure 21 is pointing to the light-emitting structure 30, and the first direction Y and the second direction X are perpendicular to each other.

The extension direction of the first groove and the direction in which the first reflector structure 21 is pointing to the light-emitting structure 30 are configured to be perpendicular to each other so that each reflective surface (the interfaces between the third semiconductor layer 212 and the first dielectric layer 211) in the first reflector structure 21 may be parallel to the sidewall of the light-emitting structure 30. Thus, it is ensured that each reflective surface in the first reflector structure 21 faces the sidewall of the light-emitting structure 30, light reflected by the first reflector structure 21 is prevented from leaking at a position other than the light emission angle, and the amount of light reflected by the first reflector structure 21 back to the light-emitting structure 30 is increased. The extension direction of the second groove and the direction in which the first reflector structure 21 is pointing to the light-emitting structure 30 are configured to be perpendicular to each other so that each reflective surface (the interfaces between the fourth semiconductor layer 222 and the second dielectric layer 221) in the second reflector structure 22 may be parallel to the sidewall of the light-emitting structure 30. Thus, it is ensured that each reflective surface in the second reflector structure 22 faces the sidewall of the light-emitting structure 30, light reflected by the second reflector structure 22 is prevented from leaking at a position other than the light emission angle, and the amount of light reflected by the second reflector structure 22 back to the light-emitting structure 30 is increased.

In an embodiment, the number of first grooves is less than the number of second grooves. The number of first grooves is set to be less than the number of second grooves so that the number of film pairs of the first reflector structure 21 is less than the number of film pairs of the second reflector structure 22. The reflectance of a DBR is determined by the number of film pairs constituting the DBR and the difference in the refractive index between the materials of layers constituting the DBR. In the case where film materials in the first reflector structure 21 are the same as the film materials in the second reflector structure 22, the number of film pairs of the second reflector structure 22 is greater than the number of film pairs of the first reflector structure 21 so that the overall reflectance of the second reflector structure 22 is greater than the overall reflectance of the first reflector structure 21, that is, the overall transmittance of the first reflector structure 21 is greater than the overall transmittance of the second reflector structure 22, and the light emission surface of the semiconductor structure is the side surface of the first reflector structure 21 facing away from the second reflector structure 22.

In another embodiment of the present disclosure, the number of second grooves may be set to be less than the number of first grooves so that the overall reflectance of the first reflector structure 21 is greater than the overall reflectance of the second reflector structure 22, and the light emission surface of the semiconductor structure is the side surface of the second reflector structure 22 facing away from the first reflector structure 21.

In an embodiment of the present disclosure, referring to FIGS. 1 and 2, the first groove has a width L1 less than 100 nm, and the interval L2 of the multiple first grooves is less than 150 nm; and the second groove has a width L3 less than 100 nm, and the interval L4 of the multiple second grooves is less than 150 nm.

The width L1 of the first groove is set to be less than 100 nm and the interval L2 of the multiple first grooves is set to be less than 150 nm so that the thickness of the first reflector structure 21 in the second direction X can be reduced. Thus, the volume of the semiconductor structure is reduced, and the miniaturization of the device is facilitated. The width L3 of the second groove is set to be less than 100 nm and the interval L4 of the multiple second grooves is set to be less than 150 nm so that the thickness of the second reflector structure 22 in the second direction X can be reduced. Thus, the volume of the semiconductor structure is reduced, and the miniaturization of the device is facilitated.

In an embodiment of the present disclosure, each of the first sub-dielectric layer 211 and the second sub-dielectric layer 221 is a single layer of material, where the material of the first sub-dielectric layer 211 includes SiO₂ or SiN, and the material of the second sub-dielectric layer 221 includes SiO₂ or SiN.

Alternatively, each of the first sub-dielectric layer 211 and the second sub-dielectric layer 221 is a stacked material layer, and each of the first sub-dielectric layer 211 and the second sub-dielectric layer 221 includes multiple stacked DBR material layers perpendicular to the substrate 10. The material of the first sub-dielectric layer 211 includes SiO₂ and SiN. In the first sub-dielectric layer 211, SiO₂ films and SiN films are stacked along the direction perpendicular to the substrate 10. The material of the second sub-dielectric layer 221 includes SiO₂ and SiN. In the second sub-dielectric layer 221, SiO₂ films and SiN films are stacked along the direction perpendicular to the substrate 10.

It is to be noted that in the first reflector structure 21, the film in contact with the sidewall of the light-emitting structure 30 is the first sub-dielectric layer 211, which avoids the phenomenon of a short circuit in the device caused by a third semiconductor layer 212 being in contact with the sidewall of the light-emitting structure 30. In the second reflector structure 22, the film in contact with the sidewall of the light-emitting structure 30 is the second sub-dielectric layer 221, which avoids the phenomenon of a short circuit in the device caused by a fourth semiconductor layer 222 being in contact with the sidewall of the light-emitting structure 30.

In an embodiment of the present disclosure, the first groove extends through or partially extends through the first sub-dielectric layer 211; and/or the second groove extends through or partially extends through the second sub-dielectric layer 221. In the first direction Y, the first groove may extend through the first sub-dielectric layer 211. In this case, the third semiconductor layer 212 in the first groove extends through the first sub-dielectric layer 211, and the length of the third semiconductor layer 212 in the first direction Y is equal to the length of the first sub-dielectric layer 211 in the first direction Y. Alternatively, in the first direction Y, the first groove may partially extend through the first sub-dielectric layer 211. In this case, the third semiconductor layer 212 in the first groove partially extends through the first sub-dielectric layer 211, and the length of the third semiconductor layer 212 in the first direction Y is less than the length of the first sub-dielectric layer 211 in the first direction Y. In an embodiment, the length of the third semiconductor layer 212 in the first direction Y is greater than or equal to the length of the light-emitting structure 30 in the first direction Y so that reflective surfaces in the first reflector structure 21 can reflect light emitted from the entire region of the side surface of the light-emitting structure 30 facing the first reflector structure 21.

In addition, in the first direction Y, the second groove may extend through the second sub-dielectric layer 221. In this case, the fourth semiconductor layer 222 in the second groove extends through the second sub-dielectric layer 221, and the length of the fourth semiconductor layer 222 in the first direction Y is equal to the length of the second sub-dielectric layer 221 in the first direction Y. Alternatively, in the first direction Y, the second groove may partially extend through the second sub-dielectric layer 221. In this case, the fourth semiconductor layer 222 in the second groove partially extends through the second sub-dielectric layer 221, and the length of the third semiconductor layer 212 in the first direction Y is less than the length of the first sub-dielectric layer 211 in the first direction Y. In an embodiment, the length of the fourth semiconductor layer 222 in the first direction Y is greater than or equal to the length of the light-emitting structure 30 in the first direction Y so that reflective surfaces in the second reflector structure 22 can reflect light emitted from the entire region of the side surface of the light-emitting structure 30 facing the second reflector structure 22.

In an embodiment of the present disclosure, referring to FIG. 3, each of the material of the third semiconductor layer 212 and the material of the fourth semiconductor layer 222 includes a Group III nitride material. The first reflector structure 21 further includes a first partition groove 201 extending along the second direction X and intersecting the multiple first grooves, and the Group III nitride material is prepared in the first partition groove 201. The second reflector structure 22 further includes a second partition groove 202 extending along the second direction X and intersecting the multiple second grooves, and the Group III nitride material is prepared in the second partition groove 202.

It is to be understood that the Group III nitride material is prepared in the first grooves, the second grooves, the first partition groove 201, and the second partition groove 202. Group III nitride materials prepared in the first grooves, the second grooves, the first partition groove 201, and the second partition groove 202 may be the same or different. The first partition groove 201 in the first reflector structure 21 extends along the second direction X, the first partition groove 201 intersects the first grooves, and the first partition groove 201 is used for partitioning the first reflector structure 21 into two parts. The second partition groove 202 in the second reflector structure 22 extends along the second direction X, the second partition groove 202 intersects the second grooves, and the second partition groove 202 is used for partitioning the second reflector structure 22 into two parts. Each pair of reflector structures and the light-emitting structure 30 disposed between the pair of reflector structures may form one light-emitting unit, which means that two light-emitting units are disposed in the semiconductor structure and two laser beams may be emitted. In an embodiment, multiple first partition grooves 201 may be provided in the first reflector structure 21 and the same number of second partition grooves 202 may be provided in the second reflector structure 22 so that more than two light-emitting units may be formed in the semiconductor structure, which is not limited in the present disclosure.

In an embodiment of the present disclosure, the Group III nitride material includes a gallium nitride material.

The first direction Y is a [11-20] crystal orientation of a hexagonal crystal system of the gallium nitride material; and the second direction X is a [1-100] crystal orientation of the hexagonal crystal system of the gallium nitride material.

The gallium nitride material is prepared in each of the first grooves, the second grooves, the first partition groove 201, and the second partition groove 202. In a preparation process, a dielectric material layer may be formed on a side surface of the substrate 10, and when the dielectric material layer is etched, multiple first grooves extending along the first direction Y and arranged at uniform intervals along the second direction X are formed in the first region Q1 and multiple second grooves extending along the first direction Y and arranged at uniform intervals along the second direction X are formed in the second region Q2. The dielectric material layer is etched continuously so that at least one first partition groove 201 extending along the second direction X is formed in the first region Q1 and at least one second partition groove 202 extending along the second direction X is formed in the second region Q2. The gallium nitride material is epitaxially provided in the first partition groove 201 and the second partition groove 202. Then, the Group III nitride material is prepared in the first grooves in the ELOG manner so that the third semiconductor layer 212 is formed, and the Group III nitride material is prepared in the second grooves in the ELOG manner so that the fourth semiconductor layer 222 is formed. The extension direction (the first direction Y) of the first grooves and the second grooves is configured to be the [11-20] crystal orientation of the hexagonal crystal system of the gallium nitride material, and the extension direction (the second direction X) of the first partition groove 201 and the second partition groove 202 is configured to be the [1-100] crystal orientation of the hexagonal crystal system of the gallium nitride material. Thus, the crystal quality of the third semiconductor layer 212 formed in each first groove can be improved, and the crystal quality of the fourth semiconductor layer 222 formed in each second groove can be improved. Further, the reflectance of the first reflector structure 21 and the reflectance of the second reflector structure 22 are effectively improved. In addition, through the ELOG manner, the difficulty in preparing the third semiconductor layer 212 in the first grooves and preparing the fourth semiconductor layer 222 in the second grooves is effectively reduced. In an embodiment, each of the width of the section of the first partition groove 201 and the width of the section of the second partition groove 202 is greater than each of the width of the first groove and the width of the second groove, and the section is a plane parallel to the substrate 10 so that the Group III nitride material is first formed in the first partition groove 201 and the second partition groove 202 and then from the first partition groove 201 and the second partition groove 202 to the first grooves and the second grooves in the ELOG manner. In other embodiments, the first groove and the second groove do not extend through the dielectric material layer, that is, each of the depth of the first groove and the depth of the second groove is less than the thickness of the dielectric material layer so that it is ensured that the third semiconductor layer 212 and the fourth semiconductor layer 222 are prepared in the preceding ELOG manner.

Based on the preceding embodiment, in an embodiment of the present disclosure, referring to FIGS. 1 to 3, the light-emitting structure 30 includes a first semiconductor layer 31, an active layer 33, and a second semiconductor layer 32 which are sequentially stacked on the substrate 10.

The first semiconductor layer 31 is disposed on the side of the substrate 10, the active layer 33 is disposed on the side of the first semiconductor layer 31 facing away from substrate 10, and the second semiconductor layer 32 is disposed on the side of the active layer 33 facing away from the substrate 10.

The material of the first semiconductor layer 31, the material of the active layer 33, and the material of the second semiconductor layer 32 each include the Group III nitride material. The semiconductor structure may be a laser using a semiconductor material such as gallium arsenide (GaAs), indium phosphide (InP), gallium nitride (GaN), aluminum nitride (AlN), indium gallium nitride (InGaN), cadmium sulfide (CdS), or zinc sulfide (ZnS) as a working substance. The semiconductor laser is a miniaturized laser using a PN junction composed of a direct bandgap semiconductor material as a working substance. The conductivity type of the first semiconductor layer 31 and the conductivity type of the second semiconductor layer 32 are opposite to each other. If the first semiconductor layer 31 is an N-type semiconductor layer, the second semiconductor layer 32 is a P-type semiconductor layer. If the first semiconductor layer 31 is a P-type semiconductor layer, the second semiconductor layer 32 is an N-type semiconductor layer.

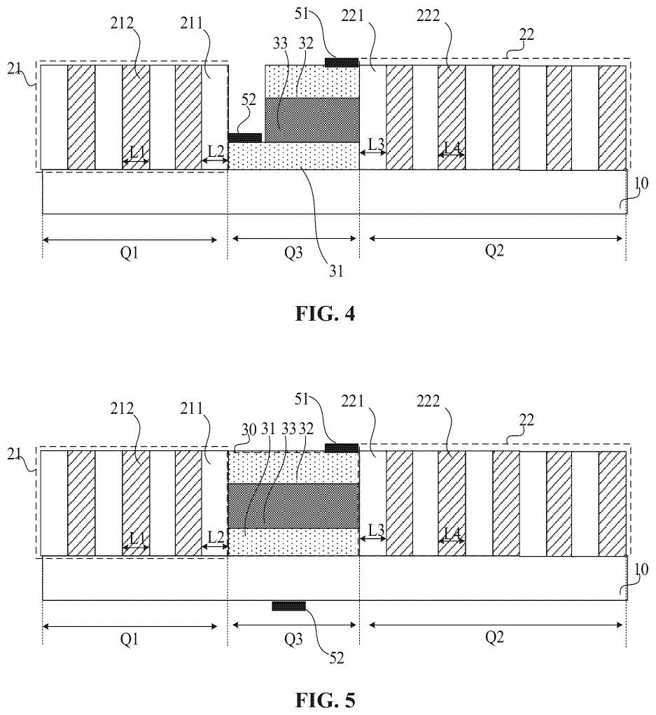

In an embodiment of the present disclosure, referring to FIGS. 4 and 5, the semiconductor structure further includes a first electrode 51 and a second electrode 52, the first electrode 51 is electrically connected to the first semiconductor layer 31, and the second electrode 52 is electrically connected to the second semiconductor layer 32.

Referring to FIG. 4, the first electrode 51 and the second electrode 52 may be disposed on the same side of the substrate 10. Alternatively, referring to FIG. 5, the first electrode 51 and the second electrode 52 may be disposed on different sides of the substrate 10. When the first electrode 51 and the second electrode 52 are disposed on the same side of the substrate 10, the first electrode 51 is disposed on the side of the second semiconductor layer 32 facing away from the substrate 10. A part of the second semiconductor layer 32 and a part of the active layer 33 are sequentially etched so that an opening in an exposed part of the first semiconductor layer 31 is formed in the light-emitting structure 30, and the second electrode 52 is disposed on the side of the exposed part of the first semiconductor layer 31 facing away from the substrate 10. When the first electrode 51 and the second electrode 52 may be disposed on the different sides of the substrate 10, the first electrode 51 is disposed on the side of the second semiconductor layer 32 facing away from the substrate 10, and the second electrode 52 is disposed on the side of the substrate 10 facing away from the light-emitting structure 30.

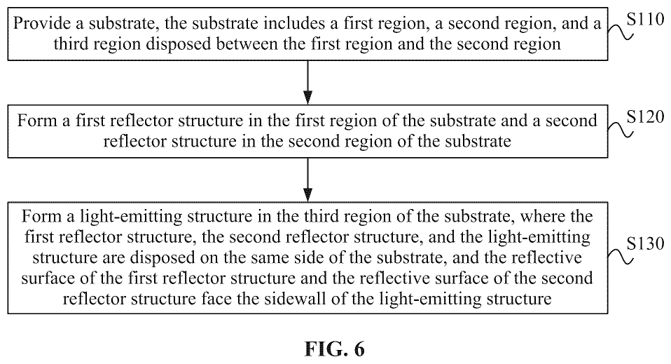

The embodiments of the present disclosure further provide a semiconductor structure preparation method for preparing the semiconductor structure according to any of the preceding embodiments. FIG. 6 is a flowchart of a semiconductor laser preparation method according to an embodiment of the present disclosure. Referring to FIG. 6, the semiconductor structure preparation method includes the steps described below.

In S110, a substrate is provided, where the substrate includes a first region, a second region, and a third region disposed between the first region and the second region.

The material of the substrate may be silicon, sapphire, SiC, or the like. A buffer layer is disposed on the surface of the substrate so that the quality and the surface of the substrate can meet the requirements for directly preparing the light-emitting structure. The material of the buffer layer may be the same as the material of the light-emitting structure or may be similar in property to the material of the light-emitting structure. Thus, the crystal quality of the Group III nitride material of the light-emitting structure can be improved.

In S120, a first reflector structure is formed in the first region of the substrate and a second reflector structure is formed the second region of the substrate.

The first reflector structure and/or the second reflector structure may be a Bragg reflector structure. The greater the number of film pairs of a DBR, the higher the reflectance of the DBR. Both the first reflector structure and the second reflector structure are configured to be the Bragg reflector structure so that light emitted from the light-emitting structure can be enhanced.

In S130, the light-emitting structure is formed in the third region of the substrate, where the first reflector structure, the second reflector structure, and the light-emitting structure are disposed on the same side of the substrate, and the reflective surface of the first reflector structure and the reflective surface of the second reflector structure face the sidewall of the light-emitting structure.

The first reflector structure, the light-emitting structure, and the second reflector structure are disposed side by side on the same side of the substrate, the light-emitting structure is disposed between the first reflector structure and the second reflector structure, and the reflective surface of the first reflector structure and the reflective surface of the second reflector structure face the sidewall of the light-emitting structure so that the first reflector structure and the second reflector structure reflect light generated by the light-emitting structure in a direction parallel to the substrate, and the light is emitted from the side surface of the light-emitting structure. The light-emitting structure may be formed on the substrate, instead of being stacked on a reflector structure in the related art, and the Group III nitride material of the light-emitting structure is prevented from being formed on the dielectric material film. Therefore, the crystal quality of the Group III nitride material of the light-emitting structure is improved, thereby improving the light emission efficiency of the semiconductor structure, reducing the risk of film cracking in the semiconductor structure, and ensuring the service life of the semiconductor structure.

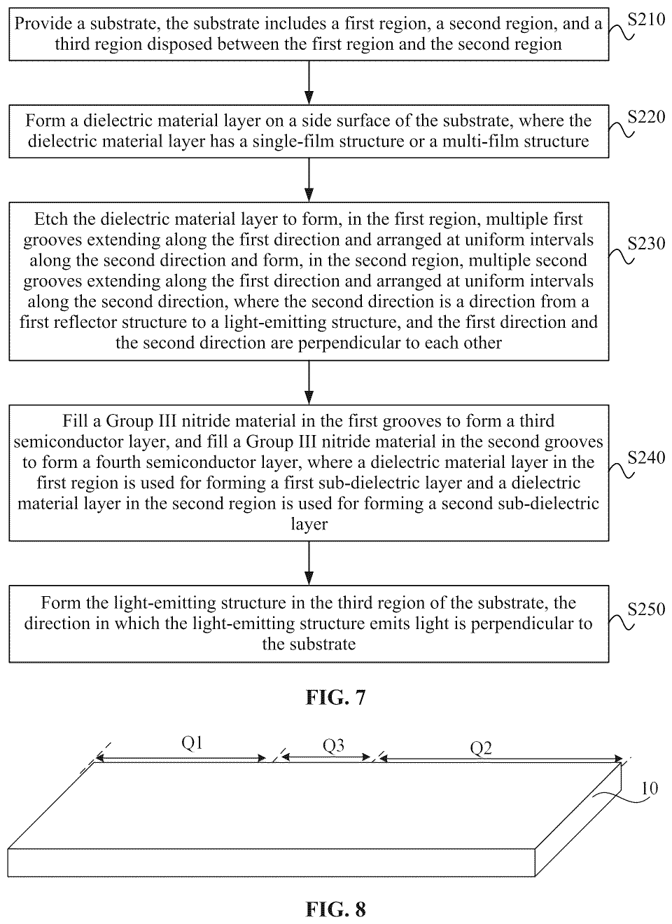

FIG. 7 is a flowchart of another semiconductor laser preparation method according to an embodiment of the present disclosure. Referring to FIG. 7, the semiconductor structure preparation method includes the steps below.

In S210, a substrate is provided, where the substrate includes a first region, a second region, and a third region disposed between the first region and the second region.

Referring to FIG. 8, the material of the substrate 10 may be silicon, sapphire, SiC, or the like. A buffer layer is disposed on the surface of the substrate 10 so that the quality and the surface of the substrate 10 can meet the requirements for directly preparing a light-emitting structure 30.

In S220, a dielectric material layer is formed on a side surface of the substrate, where the dielectric material layer has a single-film structure or a multi-film structure.

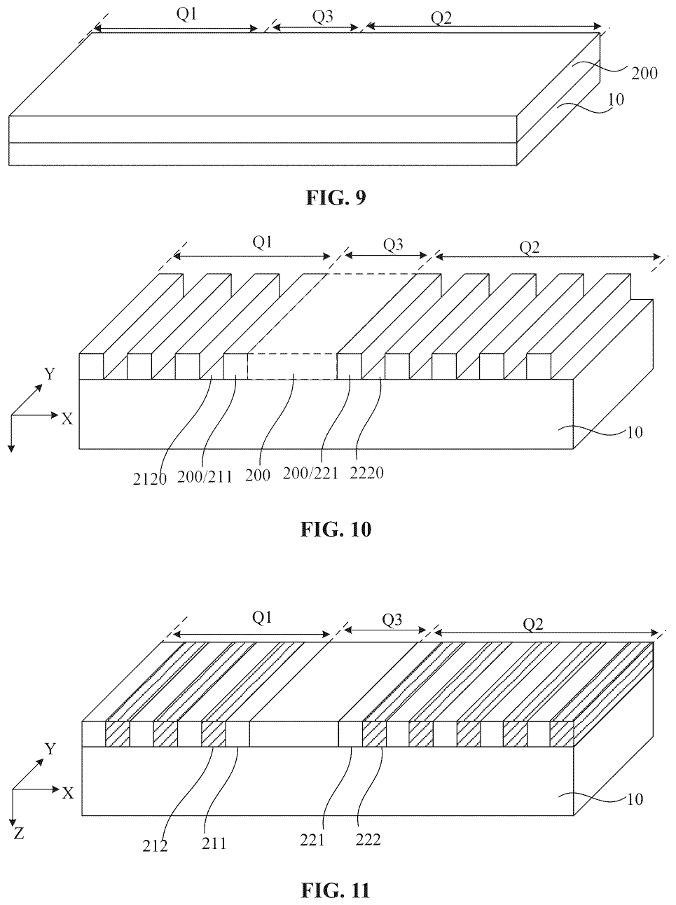

Referring to FIG. 9, a dielectric material layer 200 is formed on the side surface of the substrate 10, and the dielectric material layer 200 has a single-film structure or a multi-film structure. When the dielectric material layer 200 has the single-film structure, the material of the dielectric material layer 200 may include SiO₂ or SiN. When the dielectric material layer 200 has a multi-film structure, the material of the dielectric material layer 200 may include SiO₂ and SiN, and SiO₂ films and SiN films are stacked along the direction perpendicular to the substrate 10.

In S230, the dielectric material layer is patterned so that multiple first grooves extending along a first direction and arranged at uniform intervals along a second direction are formed in the first region and multiple second grooves extending along the first direction and arranged at uniform intervals along the second direction are formed in the second region, where the second direction is a direction in which the first reflector structure is pointing to the light-emitting structure, and the first direction and the second direction are perpendicular to each other.

Referring to FIG. 10, the dielectric material layer 200 may be patterned through a mask, and patterns in the mask may be transferred into the dielectric material layer 200. Multiple first grooves 2120 extending along the first direction Y and arranged at uniform intervals along the second direction X are formed in the first region Q1 of the substrate 10, and multiple second grooves 2220 extending along the first direction Y and arranged at uniform intervals along the second direction X are formed in the second region Q2 of the substrate 10.

In S240, a Group III nitride material is prepared in the multiple first grooves so that a third semiconductor layer is formed, and a Group III nitride material is prepared in the multiple second grooves so that a fourth semiconductor layer is formed, where a dielectric material layer in the first region is used for forming a first sub-dielectric layer and a dielectric material layer in the second region is used for forming a second sub-dielectric layer.

Referring to FIG. 11, the Group III nitride material is prepared in each first groove 2120 so that the third semiconductor layer 212 is formed, and the Group III nitride material is prepared in each second groove 2220 so that the fourth semiconductor layer 222 is formed. It is to be noted that in the first reflector structure 21, the film in contact with the sidewall of the light-emitting structure 30 is the first sub-dielectric layer 211, so as to avoid the phenomenon that the device is short-circuited when the third semiconductor layer 212 is in contact with the sidewall of the light-emitting structure 30. In the second reflector structure 22, the film in contact with the sidewall of the light-emitting structure 30 is the second sub-dielectric layer 221, so as to avoid the phenomenon that the device is short-circuited when the fourth semiconductor layer 222 is in contact with the sidewall of the light-emitting structure 30.

In S250, the light-emitting structure is formed in the third region of the substrate, where the first reflector structure, the second reflector structure, and the light-emitting structure are disposed on the same side of the substrate, and the reflective surface of the first reflector structure and the reflective surface of the second reflector structure face the sidewall of the light-emitting structure.

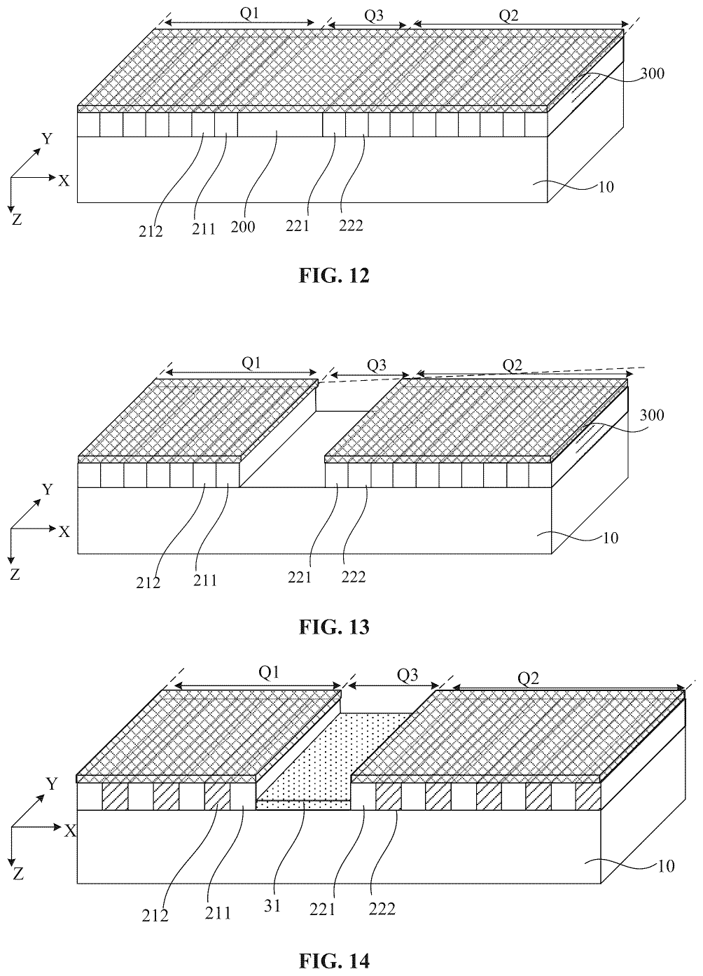

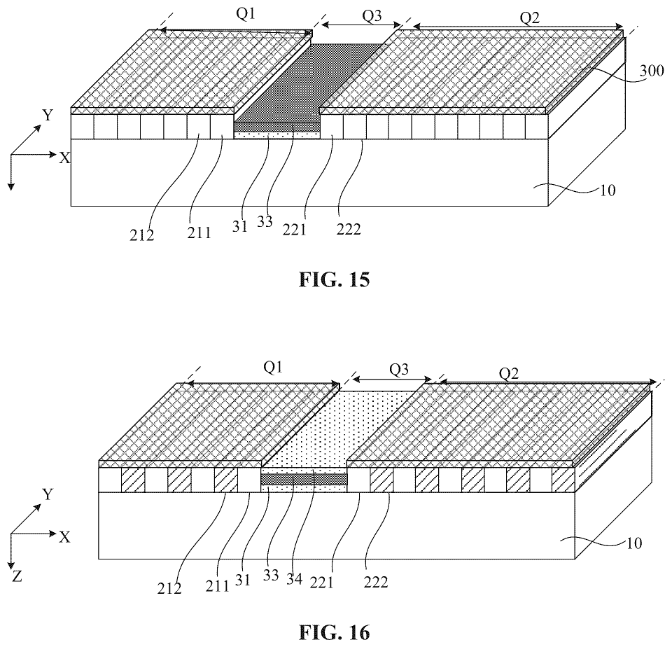

Referring to FIG. 12, a passivation layer 300 is entirely formed on the first region Q1, the second region Q2, and a third region Q3, and the passivation layer 300 may be made of a dielectric material such as SiO₂ or SiN. Referring to FIG. 13, a passivation layer 300 and a dielectric material layer 200 in the third region Q3 are etched so that the substrate 10 is exposed. Referring to FIGS. 14 to 16, a first semiconductor layer 31, an active layer 33, and a second semiconductor layer 32 are sequentially grown in the third region Q3 of the substrate 10 to form the light-emitting structure 30. When the passivation layer 300 is used for growing the semiconductor material in the third region Q3, the semiconductor material is prevented from being grown in the first region Q1 and the second region Q2. The passivation layer 300 is also used for protecting DBR material layers on two sides. The first reflector structure 21, the light-emitting structure 30, and the second reflector structure 22 are disposed side by side on the same side of the substrate 10, and it is only necessary to ensure that the quality and the surface of the substrate 10 can meet the requirements for directly preparing the light-emitting structure 30 so that the light emission efficiency of the semiconductor structure can be improved, the risk of film cracking in the semiconductor structure can be reduced, and the service life of the semiconductor structure can be ensured.

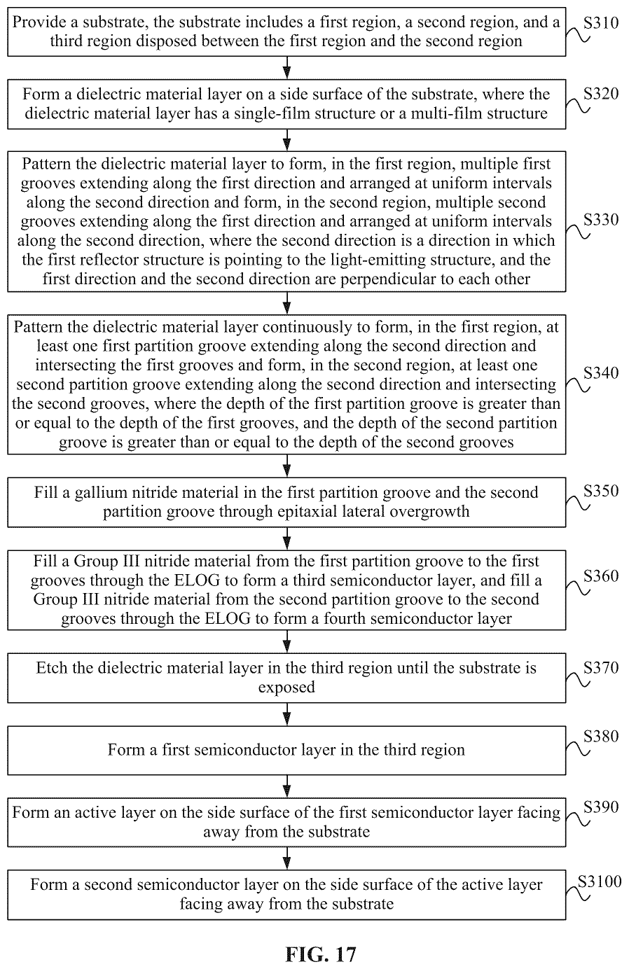

FIG. 17 is a flowchart of another semiconductor laser preparation method according to an embodiment of the present disclosure. Referring to FIG. 17, the semiconductor structure preparation method includes the steps described below.

In S310, a substrate is provided, and the substrate includes a first region, a second region, and a third region disposed between the first region and the second region.

In S320, a dielectric material layer is formed on the side surface of the substrate, where the dielectric material layer has a single-film structure or a multi-film structure.

In S330, the dielectric material layer is patterned so that multiple first grooves extending along the first direction and arranged at uniform intervals along the second direction are formed in the first region and multiple second grooves extending along the first direction and arranged at uniform intervals along the second direction are formed in the second region, where the second direction is a direction in which the first reflector structure is pointing to the light-emitting structure, and the first direction and the second direction are perpendicular to each other.

In S340, the dielectric material layer is continuously patterned so that at least one first partition groove extending along the second direction and intersecting the multiple first grooves is formed in the first region and at least one second partition groove extending along the second direction and intersecting the multiple second grooves is formed in the second region, where the depth of the first partition groove is greater than or equal to the depth of the first groove, and the depth of the second partition groove is greater than or equal to the depth of the second groove.

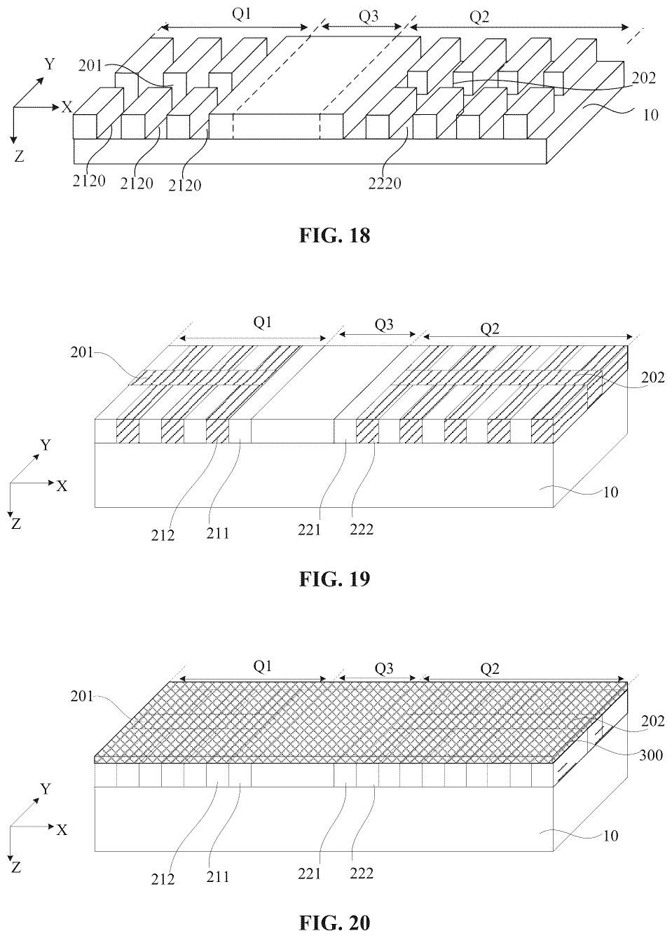

Referring to FIG. 18, the first partition groove 201 extends along the second direction X and intersects the first grooves 2120, and the second partition groove 202 extends along the second direction X and intersects the second grooves 2220.

In S350, a Group III nitride material is prepared in the first partition groove and the second partition groove.

In S360, the Group III nitride material is prepared from the first partition groove to the multiple first grooves in the ELOG manner to fill the first grooves so that a third semiconductor layer is formed, and the Group III nitride material is prepared from the second partition groove to the multiple second grooves in the ELOG manner to fill the second grooves so that a fourth semiconductor layer is formed.

Referring to FIG. 19, the Group III nitride material is prepared in each of the first grooves 2120, the second grooves 2220, the first partition groove 201, and the second partition groove 202. For example, the Group III nitride material may be a gallium nitride material. The gallium nitride material is epitaxially provided in the first partition groove 201 and the second partition groove 202. Then, the Group III nitride material is prepared in the first grooves 2120 in the ELOG manner to fill the first grooves 2120 so that the third semiconductor layer 212 is formed, and the Group III nitride material is prepared in the second grooves 2220 to fill the second grooves 2220 in the ELOG manner so that the fourth semiconductor layer 222 is formed. The extension direction (the first direction Y) of the first grooves 2120 and the second grooves 2220 is configured to be the [11-20] crystal orientation of a hexagonal crystal system of the gallium nitride material, and the extension direction (the second direction X) of the first partition groove 201 and the second partition groove 202 is configured to be the [1-100] crystal orientation of the hexagonal crystal system of the gallium nitride material. Thus, the crystal quality of the third semiconductor layer 212 formed in the first grooves 2120 can be improved, and the crystal quality of the fourth semiconductor layer 222 formed in the second grooves 2220 can be improved.

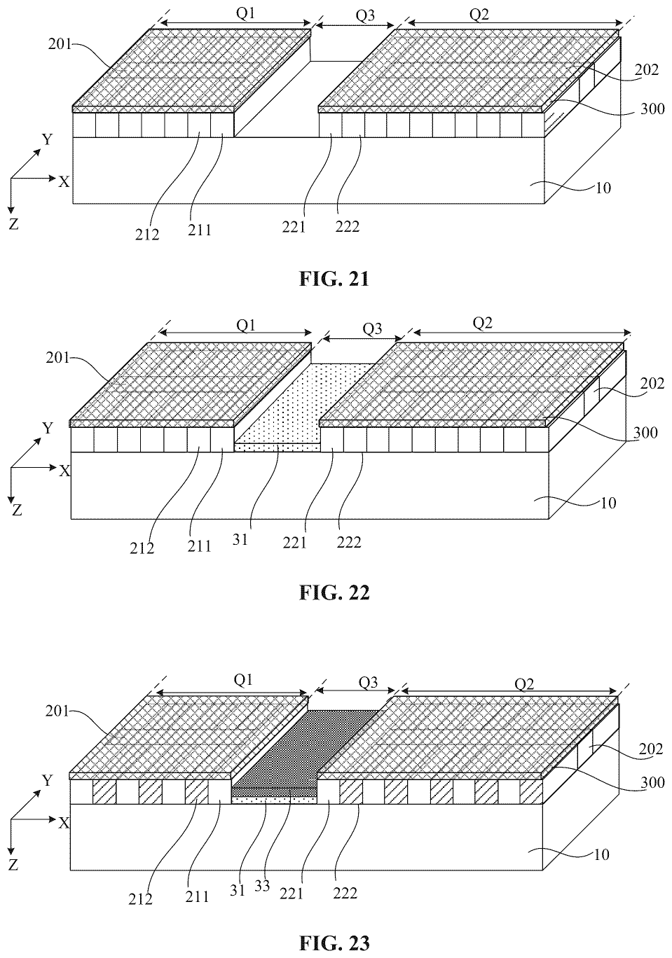

In S370, the dielectric material layer in the third region is etched until the substrate is exposed. Referring to FIG. 20, a passivation layer 300 is formed on the surface of the device before the dielectric material layer in the third region is etched. For the action of the passivation layer 300, reference may be made to the preceding embodiments, which are not repeated here. Referring to FIG. 21, the passivation layer 300 in the third region Q3 and the dielectric material layer in the third region Q3 are etched until the substrate 10 is exposed.

In S380, a first semiconductor layer is formed in the third region. Referring to FIG. 22, the first semiconductor layer 31 is formed in the third region Q3. The material of the first semiconductor layer 31 includes the Group III nitride material.

In S390, an active layer is formed on the side surface of the first semiconductor layer facing away from the substrate. Referring to FIG. 23, the active layer 33 is formed on the side surface of the first semiconductor layer 31 facing away from the substrate 10. The material of the active layer 33 includes the Group III nitride material.

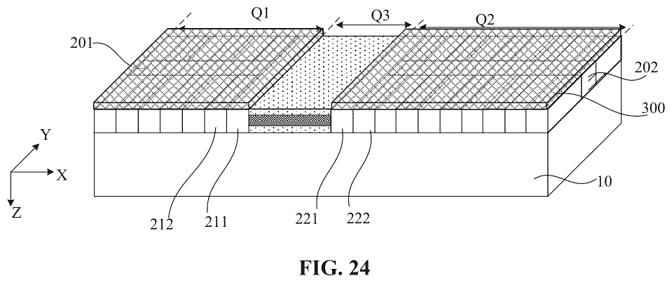

In S3100, a second semiconductor layer is formed on the side surface of the active layer facing away from the substrate. Referring to FIG. 24, the second semiconductor layer 32 is formed on the side surface of the active layer 33 facing away from the substrate 10. The material of the second semiconductor layer 32 includes the Group III nitride material. The conductivity type of the first semiconductor layer 31 and the conductivity type of the second semiconductor layer 32 are different from each other.

Based on the preceding embodiments, in the semiconductor preparation method provided by the embodiment of the present disclosure, the step of preparing the Group III nitride material in the first grooves 2120 to fill the first grooves 2120 to form the third semiconductor layer 212 and preparing the Group III nitride material in the second grooves 2220 to fill the second grooves 2220 to form the fourth semiconductor layer 222 includes the following: The dielectric material layer is patterned so that at least one first partition groove 201 extending along the second direction X is formed in the first region Q1 and at least one second partition groove 202 extending along the second direction X is formed in the second region Q2, where the depth of the first partition groove 201 is greater than or equal to the depth of the first groove 2120, and the depth of the second partition groove 202 is greater than or equal to the depth of the second groove 2220; the Group III nitride material is prepared in the first partition groove 201 and the second partition groove 202; the Group III nitride material is prepared in the multiple first grooves 2120 through the ELOG to fill the multiple first grooves 2120 so that the third semiconductor layer 212 is formed, and the Group III nitride material is prepared in the multiple second grooves 2220 through the ELOG to fill the multiple second grooves 2220 so that the fourth semiconductor layer 222 is formed. The step of forming the light-emitting structure 30 in the third region Q3 of the substrate 10 includes the following: The dielectric material layer in the third region Q3 is etched until the substrate 10 is exposed; the first semiconductor layer 31 is formed in the third region Q3; the active layer 33 is formed on the side surface of the first semiconductor layer 31 facing away from the substrate 10; and the second semiconductor layer 32 is formed on the side surface of the active layer 33 facing away from the substrate 10.

In the semiconductor laser preparation method according to the preceding embodiments, the first reflector structure is formed in the first region of the substrate and the second reflector structure is formed in the second region of the substrate, and then the light-emitting structure is formed in the third region of the substrate. Alternatively, the light-emitting structure is formed in the third region of the substrate, and then the first reflector structure may be formed in the first region of the substrate and the second reflector structure may be formed in the second region of the substrate.

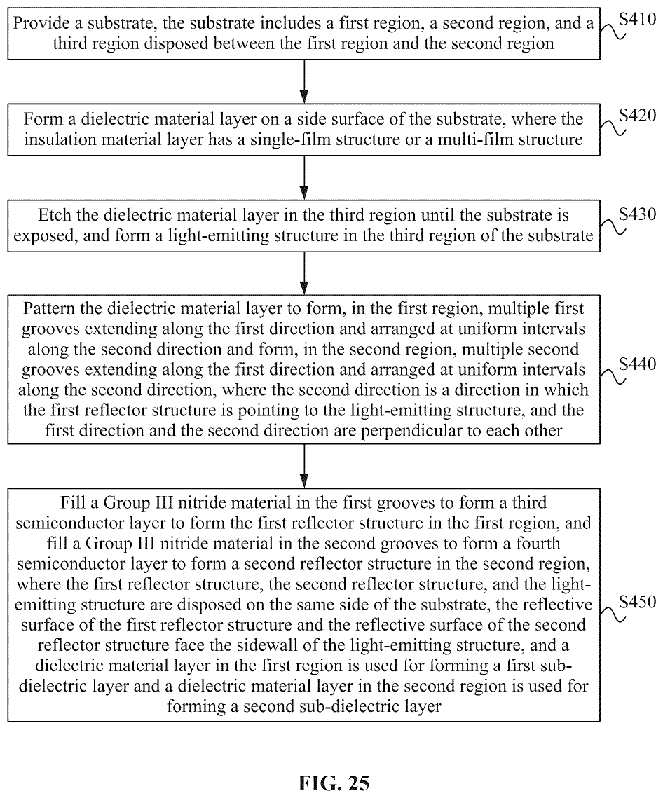

FIG. 25 is a flowchart of another semiconductor laser preparation method according to an embodiment of the present disclosure. Referring to FIG. 25, the semiconductor structure preparation method includes the steps described below.

In S410, a substrate is provided, and the substrate includes a first region, a second region, and a third region disposed between the first region and the second region. For the structure, reference may be made to FIG. 8, which will not be repeated here.

In S420, a dielectric material layer is formed on the side surface of the substrate, where the dielectric material layer has a single-film structure or a multi-film structure. For the structure, reference may be made to FIG. 9, which will not be repeated here.

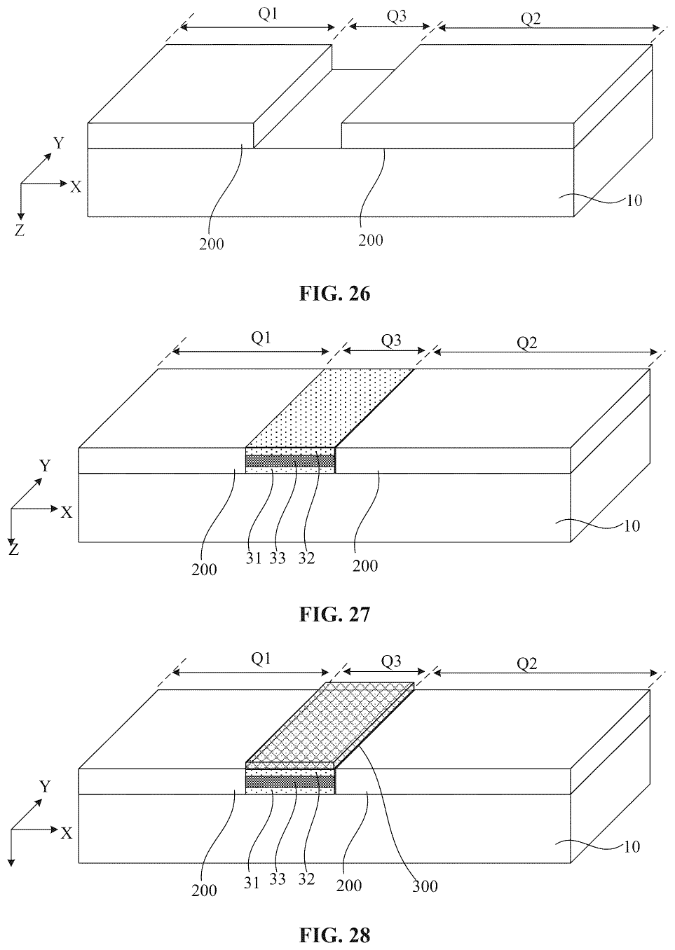

In S430, a dielectric material layer in the third region is etched until the substrate is exposed, and a light-emitting structure is formed in the third region of the substrate. For the structure, reference may be made to FIGS. 26 and 27, which will not be repeated here.

In S440, the dielectric material layer is patterned so that multiple first grooves extending along the first direction and arranged at uniform intervals along the second direction are formed in the first region and multiple second grooves extending along the first direction and arranged at uniform intervals along the second direction are formed in the second region, where the second direction is a direction in which the first reflector structure is pointing to the light-emitting structure, and the first direction and the second direction are perpendicular to each other.

In S450, a Group III nitride material is prepared in the multiple first grooves to fill the multiple first grooves and further to form a third semiconductor layer so that the first reflector structure is formed in the first region, and a Group III nitride material is prepared in the multiple second grooves to fill the multiple second grooves and further to form a fourth semiconductor layer so that the second reflector structure is formed in the second region. The first reflector structure, the second reflector structure, and the light-emitting structure are disposed on the same side of the substrate, the reflective surface of the first reflector structure and the reflective surface of the second reflector structure face the sidewall of the light-emitting structure, and a dielectric material layer in the first region is used for forming a first sub-dielectric layer and a dielectric material layer in the second region is used for forming a second sub-dielectric layer. For the structure, reference may be made to FIG. 30, and the details are not repeated here. In an embodiment, referring to FIG. 28, before step S450, a passivation layer 300 may be formed on the light-emitting structure first, and the function of the passivation layer 300 is to protect the light-emitting structure and prevent the Group III nitride material from being epitaxially provided on the light-emitting structure.

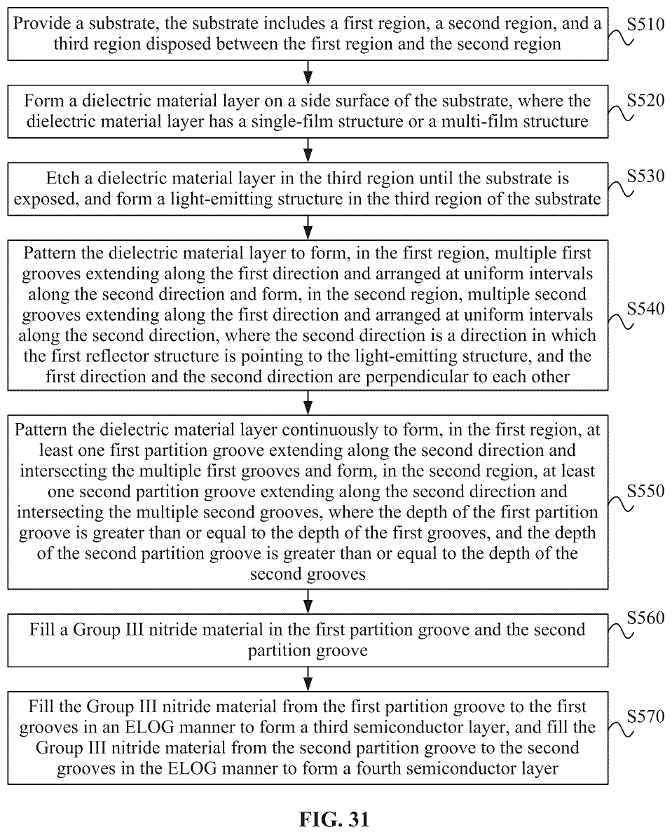

FIG. 31 is a flowchart of another semiconductor laser preparation method according to an embodiment of the present disclosure. Referring to FIG. 31, the semiconductor structure preparation method includes the steps described below.

In S510, a substrate is provided, where the substrate includes a first region, a second region, and a third region disposed between the first region and the second region. For the structure, reference may be made to FIG. 8, and the details are not repeated here.

In S520, a dielectric material layer is formed on the side surface of the substrate, where the dielectric material layer has a single-film structure or a multi-film structure. For the structure, reference may be made to FIG. 9, and the details are not repeated here.

In S530, a dielectric material layer in the third region is etched until the substrate is exposed, and a light-emitting structure is formed in the third region of the substrate. For the structure, reference may be made to FIGS. 26 and 27, and the details are not repeated here.

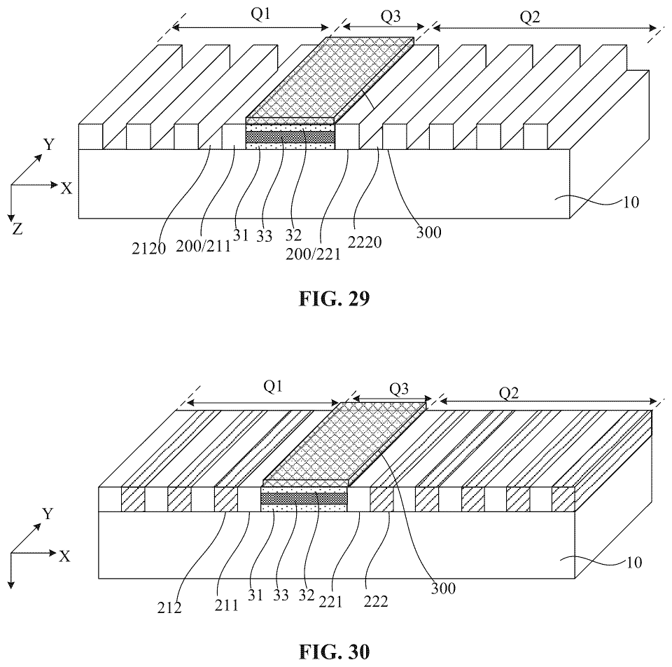

In S540, the dielectric material layer is patterned so that multiple first grooves extending along the first direction and arranged at uniform intervals along the second direction are formed in the first region and multiple second grooves extending along the first direction and arranged at uniform intervals along the second direction are formed in the second region, where the second direction is a direction in which the first reflector structure is pointing to the light-emitting structure, and the first direction and the second direction are perpendicular to each other. For the structure, reference may be made to FIGS. 28 and 29, and the details are not repeated here.

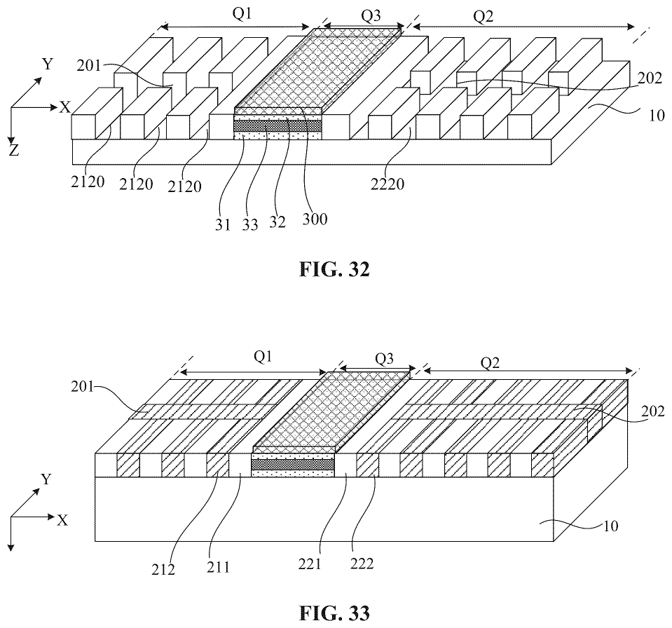

In S550, the dielectric material layer is continuously patterned so that at least one first partition groove extending along the second direction and intersecting the multiple first grooves is formed in the first region and at least one second partition groove extending along the second direction and intersecting the multiple second grooves is formed in the second region, where the depth of the first partition groove is greater than or equal to the depth of the first groove, and the depth of the second partition groove is greater than or equal to the depth of the second groove. For the structure, reference is made to FIG. 32, and the details are not repeated here.

In S560, a Group III nitride material is prepared in the first partition groove and the second partition groove. In an embodiment, referring to FIG. 32, before step S560, a passivation layer 300 may be prepared on the light-emitting structure in the third region, and the function of the passivation layer 300 is to protect the light-emitting structure and to prevent the Group III nitride material from being epitaxially provided on the light-emitting structure.

In S570, the Group III nitride material is prepared from the first partition groove to the first grooves through ELOG to fill the first grooves so that the third semiconductor layer is formed, and the Group III nitride material is prepared from the second partition groove to the second grooves through the ELOG to fill the second grooves so that the fourth semiconductor layer is formed. For the structure, reference is made to FIG. 33, and the details are not repeated here.

Based on any of the preceding embodiments, referring to FIG. 5, after the light-emitting structure 30 is formed in the third region Q3 of the substrate 10, the method further includes the steps described below.

A first electrode 51 is formed on the side of the second semiconductor layer 32 facing away from the substrate 10.

A second electrode 52 is formed on the side of the substrate 10 facing away from the light-emitting structure 30.

Alternatively, referring to FIG. 4, after the light-emitting structure 30 is formed in the third region Q3 of the substrate 10, the method further includes the steps below.

A part of the second semiconductor layer 32 and a part of the active layer 33 are etched sequentially until a part of the first semiconductor layer 31 is exposed.

A first electrode 51 is formed on the side of the second semiconductor layer 32 facing away from the substrate 10.

A second electrode 52 is formed on the side of the exposed part of the first semiconductor layer 31 facing away from the substrate 10.

According to the technical schemes provided by the embodiments of the present disclosure, the first reflector structure, the light-emitting structure, and the second reflector structure are disposed side by side on the same side of the substrate, the light-emitting structure is disposed between the first reflector structure and the second reflector structure, and each of the reflective surface of the first reflector structure and the reflective surface of the second reflector structure faces the sidewall of the light-emitting structure so that the first reflector structure and the second reflector structure reflect light generated by the light-emitting structure in a direction parallel to the substrate, and the light is emitted from a side surface of the semiconductor structure. The light-emitting structure is formed on the substrate, instead of being stacked on a reflector in the related art. Therefore, the crystal quality of the Group III nitride material of the light-emitting structure can be improved, thereby improving the light emission efficiency of the semiconductor structure, reducing the risk of film cracking in the semiconductor structure, and ensuring the service life of the semiconductor structure.

It is to be noted that the preceding are only alternative embodiments of the present disclosure and the technical principles used therein. It is to be understood by those skilled in the art that the present disclosure is not limited to the embodiments described herein. For those skilled in the art, various apparent modifications, adaptations, and substitutions can be made without departing from the scope of the present disclosure. Therefore, while the present disclosure has been described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A semiconductor structure, comprising:
a substrate, wherein the substrate comprises a first region, a second region, and a third region disposed between the first region and the second region;
a first reflector structure disposed in the first region of the substrate;
a second reflector structure disposed in the second region of the substrate, wherein the first reflector structure and the second reflector structure are disposed on a same side of the substrate; and
a light-emitting structure disposed in the third region of the substrate, wherein the light-emitting structure is disposed on the same side of the substrate as the first reflector structure;
wherein each of a reflective surface of the first reflector structure and a reflective surface of the second reflector structure faces a sidewall of the light-emitting structure.

2. The semiconductor structure according to claim 1, wherein at least one of the first reflector structure or the second reflector structure is a Bragg reflector structure,
wherein the first reflector structure comprises a first sub-dielectric layer covering the sidewall of the light-emitting structure, and the first sub-dielectric layer is provided with a plurality of first grooves uniformly distributed and a third semiconductor layer prepared in each of the plurality of first grooves; and
the second reflector structure comprises a second sub-dielectric layer covering the sidewall of the light-emitting structure, and the second sub-dielectric layer is provided with a plurality of second grooves uniformly distributed and a fourth semiconductor layer prepared in each of the plurality of second grooves.

3. The semiconductor structure according to claim 2, wherein each of the plurality of first grooves extends along a first direction, and the plurality of first grooves are arranged at intervals along a second direction; and
each of the plurality of second grooves extends along the first direction, and the plurality of second grooves are arranged at intervals along the second direction;
wherein the second direction is a direction in which the first reflector structure is pointing to the light-emitting structure, and the first direction and the second direction are perpendicular to each other.

4. The semiconductor structure according to claim 2, wherein a number of the plurality of first grooves is less than a number of the plurality of second grooves.

5. The semiconductor structure according to claim 2, wherein a first groove of the plurality of first grooves has a width less than 100 nm, and an interval between the plurality of first grooves is less than 150 nm; and
a second groove of the plurality of second grooves has a width less than 100 nm, and an interval between the plurality of second grooves is less than 150 nm.

6. The semiconductor structure according to claim 2, wherein each of the first sub-dielectric layer and the second sub-dielectric layer is a single layer of material, wherein a material of the first sub-dielectric layer comprises SiO₂ or SiN, and a material of the second sub-dielectric layer comprises SiO₂ or SiN; or
the first sub-dielectric layer and the second sub-dielectric layer are each a stacked material layer, and each of the first sub-dielectric layer and the second sub-dielectric layer comprises a plurality of stacked distributed Bragg reflector (DBR) material layers perpendicular to the substrate, wherein a material of the first sub-dielectric layer comprises SiO₂ and SiN, and a material of the second sub-dielectric layer comprises SiO₂ and SiN.

7. The semiconductor structure according to claim 2, wherein a first groove of the plurality of first grooves extends through the first sub-dielectric layer or partially extends through the first sub-dielectric layer; and/or
a second groove of the plurality of second grooves extends through the second sub-dielectric layer or partially extends through the second sub-dielectric layer.

8. The semiconductor structure according to claim 3, wherein a material of the third semiconductor layer and a material of the fourth semiconductor layer each comprise a Group III nitride material;
the first reflector structure further comprises a first partition groove extending along the second direction and intersecting the plurality of first grooves, and the Group III nitride material is prepared in the first partition groove; and
the second reflector structure further comprises a second partition groove extending along the second direction and intersecting the plurality of second grooves, and the Group III nitride material is prepared in the second partition groove.

9. The semiconductor structure according to claim 8, wherein the Group III nitride material comprises a gallium nitride material;
wherein the first direction is a [11-20] crystal orientation of a hexagonal crystal system of the gallium nitride material; and the second direction is a [1-100] crystal orientation of the hexagonal crystal system of the gallium nitride material.

10. The semiconductor structure according to claim 8, wherein along a direction perpendicular to the substrate, a depth of the first partition groove is greater than or equal to a thickness of the first reflector structure; and/or
along a direction perpendicular to the substrate, a depth of the second partition groove is greater than or equal to a thickness of the second reflector structure.

11. The semiconductor structure according to claim 1, wherein the light-emitting structure comprises a first semiconductor layer, an active layer, and a second semiconductor layer which are sequentially stacked on the substrate;
wherein the first semiconductor layer and the second semiconductor layer have opposite conductivity types.

12. The semiconductor structure according to claim 11, wherein each of a material of the first semiconductor layer, a material of the active layer, and a material of the second semiconductor layer comprises a Group III nitride material.

13. The semiconductor structure according to claim 11, further comprising: a first electrode and a second electrode, wherein the first electrode is electrically connected to the first semiconductor layer, and the second electrode is electrically connected to the second semiconductor layer.

14. A semiconductor structure preparation method for preparing a semiconductor structure, wherein the semiconductor structure comprises a substrate, a first reflector structure disposed in a first region of the substrate; a second reflector structure disposed in a second region of the substrate; and a light-emitting structure disposed in a third region of the substrate;
wherein the semiconductor structure preparation method comprises:
providing the substrate, wherein the substrate comprises the first region, the second region, and the third region disposed between the first region and the second region; and
forming the first reflector structure in the first region of the substrate, the second reflector structure in the second region of the substrate, and the light-emitting structure in the third region of the substrate respectively, wherein the first reflector structure, the second reflector structure, and the light-emitting structure are disposed on a same side of the substrate, and each of a reflective surface of the first reflector structure and a reflective surface of the second reflector structure faces a sidewall of the light-emitting structure.

15. The semiconductor structure preparation method according to claim 14, wherein forming the first reflector structure in the first region of the substrate, the second reflector structure in the second region of the substrate, and the light-emitting structure in the third region of the substrate respectively comprises:
forming the light-emitting structure in the third region of the substrate after the first reflector structure is formed in the first region of the substrate and the second reflector structure is formed in the second region of the substrate; or
forming the first reflector structure in the first region of the substrate and the second reflector structure in the second region of the substrate separately after the light-emitting structure is formed in the third region of the substrate.

16. The semiconductor structure preparation method according to claim 14, wherein forming the first reflector structure in the first region of the substrate and the second reflector structure in the second region of the substrate comprises:
forming a dielectric material layer on a side surface of the substrate, wherein the dielectric material layer has a single-film structure or a multi-film structure;
patterning the dielectric material layer to form a plurality of first grooves in the first region and a plurality of second grooves in the second region, wherein the plurality of first grooves extend along a first direction and are arranged at uniform intervals along a second direction, the plurality of second grooves extend along the first direction and are arranged at uniform intervals along the second direction, the second direction is a direction in which the first reflector structure is pointing to the light-emitting structure, and the first direction and the second direction are perpendicular to each other; and
preparing a Group III nitride material in each of the plurality of first grooves to form a third semiconductor layer, and preparing a Group III nitride material in each of the plurality of second grooves to form a fourth semiconductor layer, wherein a dielectric material layer in the first region is used for forming a first sub-dielectric layer and a dielectric material layer in the second region is used for forming a second sub-dielectric layer.

17. The semiconductor structure preparation method according to claim 16, wherein patterning the dielectric material layer further comprises:
forming at least one first partition groove in the first region and at least one second partition groove in the second region, wherein the at least one first partition groove extends along the second direction and intersects the plurality of first grooves, the at least one second partition groove extends along the second direction and intersects the plurality of second grooves, a depth of the at least one first partition groove is greater than or equal to a depth of a first groove among the plurality of first grooves, and a depth of the at least one second partition groove is greater than or equal to a depth of a second groove among the plurality of second grooves; and
wherein preparing the Group III nitride material in each of the plurality of first grooves to form the third semiconductor layer, and preparing the Group III nitride material in each of the plurality of second grooves to form the fourth semiconductor layer comprises:
preparing the Group III nitride material in the at least one first partition groove and the at least one second partition groove; and
preparing the Group III nitride material from the at least one first partition groove to each of the plurality of first grooves in an epitaxial lateral overgrowth manner to form the third semiconductor layer, and preparing the Group III nitride material from the at least one second partition groove to the plurality of second grooves in the epitaxial lateral overgrowth manner to form the fourth semiconductor layer.

18. The semiconductor structure preparation method according to claim 14, wherein forming the light-emitting structure in the third region of the substrate comprises:
etching a dielectric material layer in the third region until the substrate is exposed;
forming a first semiconductor layer in the third region;
forming an active layer on a side surface of the first semiconductor layer facing away from the substrate; and
forming a second semiconductor layer on a side surface of the active layer facing away from the substrate.

19. The semiconductor structure preparation method according to claim 18, wherein after forming the light-emitting structure in the third region of the substrate, the method further comprises one of the following:
forming a first electrode on a side of the second semiconductor layer facing away from the substrate, and forming a second electrode on a side of the substrate facing away from the light-emitting structure; or
etching a part of the second semiconductor layer and a part of the active layer sequentially until a part of the first semiconductor layer is exposed, forming a first electrode on a side of the second semiconductor layer facing away from the substrate, and forming a second electrode on a side of the exposed part of the first semiconductor layer facing away from the substrate.

20. The semiconductor structure preparation method according to claim 14, wherein at least one of the first reflector structure or the second reflector structure is a Bragg reflector structure,
wherein the first reflector structure comprises a first sub-dielectric layer covering the sidewall of the light-emitting structure, and the first sub-dielectric layer is provided with a plurality of first grooves uniformly distributed and a third semiconductor layer prepared in each of the plurality of first grooves; and
the second reflector structure comprises a second sub-dielectric layer covering the sidewall of the light-emitting structure, and the second sub-dielectric layer is provided with a plurality of second grooves uniformly distributed and a fourth semiconductor layer prepared in each of the plurality of second grooves.
